(19) United States
(12) Patent Application Publication
(10) Pub. No.: US 2020/0185322 A1
(43) Pub. Date: Jun. 11, 2020

(54) SEMICONDUCTOR DEVICE CONNECTIONS WITH SINTERED NANOPARTICLES

(71) Applicant: Texas Instruments Incorporated, Dallas, TX (US)

(72) Inventors: Rongwei Zhang, Plano, TX (US); Vikas Gupta, Dallas, TX (US)

(21) Appl. No.: 16/213,557

(22) Filed: Dec. 7, 2018

(51) Int. Cl. H01L 23/498; H01L 23/00; H01L 21/48

(52) U.S. Cl. CPC H01L 23/49894; H01L 23/49816; H01L 23/49838; H01L 24/13; H01L 24/16; H01L 21/4853; H01L 2224/81203; H01L 21/4867; H01L 2224/13147; H01L 2924/014; H01L 2224/16227; H01L 2924/15323; H01L 2924/15331; H01L 24/81

(57) ABSTRACT

In a described example, a packaged device includes a substrate having a device mounting surface with conductive lands having a first thickness spaced from one another on the device mounting surface. A first polymer layer is disposed on the device mounting surface between the conductive lands having a second thickness equal to the first thickness. The conductive lands have an outer surface not covered by the first polymer layer. A second polymer layer is disposed on the first polymer layer, the outer surface of the conductive lands not covered by the second polymer layer. Conductive nanoparticle material is disposed on the outer surface of the conductive lands. A third polymer layer is disposed on the second polymer layer between the conductive nanoparticle material on the conductive lands. At least one semiconductor device die is mounted to the third polymer layer having electrical terminals bonded to the conductive nanoparticle material.

### TECHNICAL FIELD

This disclosure relates generally to semiconductor devices, and more particularly to semiconductor devices mounted on a substrate.

### BACKGROUND

As semiconductor processes continue to advance, semiconductor devices are increasingly smaller. The distance between terminals (“pitch”) on a surface of the semiconductor devices continues to shrink. Further, the desire for chip scale packages, where the package size is approximately the same area as the die area, and the continuing need for mounting semiconductor device dies to a chip carrier or circuit board without the need for additional substrates, interposers or carriers is increasing. Flip chip mounting is used to mount terminals on a semiconductor device die to a carrier or substrate. Flip chip packages require making vertical or “z” connections between terminals of the semiconductor device die and conductive pads or lands on the substrate. To reduce the surface area needed for mounting dies, connections that extend in the “x” or “y” direction, such as bond wires, ribbon bonds, or redistribution layers, are undesirable, as these connections increase board area. Vertical connections are made between bond pads on the circuit side of a semiconductor device die and conductive lands on a substrate such as a chip carrier or circuit board using solder bumps, solder balls, conductive pillars such as copper pillar bumps, and copper studs, such connections preserve total board area by extending from the bond pads on the semiconductor device die to the lands in a vertical or “z” direction.

To make the electrical connection between devices and boards, anisotropic conductive film (ACF) and anisotropic conductive adhesive (ACA) have been used. Conductive spheres are placed in a tape or film or adhesive. The film carrying the conductive spheres is disposed between the die bond pads or copper pads on the semiconductor device die and the lands on the substrate. By using a combination of thermal and compressive energy, conductive paths are formed through the ACF in a vertical direction between the bond pads on the semiconductor die and the conductive lands on the substrate. However, because the conductive spheres in ACF are randomly distributed, unwanted shorts between the pads can form because conductive paths occasionally occur in the “x” or “y” direction. Further, the conductivity or resistance characteristics of different electrical connections in the finished device can vary, as the number of spheres that form a conductive path can also vary, due to the random distribution of the conductive spheres in the ACF.

Fixed placement of the spheres in a tape or film can be used, this increases cost of the film and requires alignment with the bond pads and lands of the semiconductor device and board being used. Metal studs can be formed and disposed in known placements in a film, again increasing costs.

### SUMMARY

In a described example, a packaged device includes a substrate having a device mounting surface with conductive lands having a first thickness spaced from one another on the device mounting surface. A first polymer layer is disposed on the device mounting surface between the conductive lands having a second thickness equal to the first thickness. The conductive lands have an outer surface not covered by the first polymer layer. A second polymer layer is disposed on the first polymer layer, the outer surface of the conductive lands not covered by the second polymer layer. Conductive nanoparticle material is disposed on the outer surface of the conductive lands. A third polymer layer is disposed on the second polymer layer between the conductive lands. At least one semiconductor device die is mounted to the third polymer layer having electrical terminals bonded to the conductive nanoparticle material.

### BRIEF DESCRIPTION OF THE DRAWINGS

FIGS. 1A-1G are cross sectional views illustrating steps of an example process for forming an arrangement.

FIG. 2 is a flow diagram of a method for forming an arrangement.

FIG. 3 is a flow diagram for an alternative method for forming an arrangement.

FIG. 4 illustrates in a cross an arrangement for a packaged device.

FIG. 5 is a projection view of a packaged device.

FIG. 6 is a cross section of a packaged device arrangement for a multiple chip module.

FIG. 7 is a projection view and a plan view for an alternative packaged device.

### DETAILED DESCRIPTION

Corresponding numerals and symbols in the different figures generally refer to corresponding parts unless otherwise indicated. The figures are not necessarily drawn to scale.

In this description, the term “semiconductor device” is used. A semiconductor device is a device formed on a semiconductor substrate. Semiconductor devices include integrated circuits where several, hundreds or thousands of individual devices such as transistors are formed on a semiconductor substrate and are then coupled to one another using conductive conductors formed over an active surface of the semiconductor substrate to form a complete circuit function. Integrated circuits can include processors, analog-to-digital converters, memories and other integrated devices. The term semiconductor device also includes discrete devices formed on semiconductor substrates such as discrete transistors, power field-effect-transistors (FETs), switching power converters, relays, diodes, opto-couplers, microwave circuits, and other device such as passive devices such as silicon controlled rectifiers (SCRs), resistors, capacitors, transformers, inductors and transducers. In this description, the term “semiconductor device die” is used. As used herein, a semiconductor device die is a single semiconductor device initially formed with many other semiconductor devices on a semiconductor wafer, and then separated from the semiconductor wafer by a dicing process referred to as “singulation.” In this description the term “substrate” is used. As used herein, the term “substrate” includes a molded interconnect substrate (MIS), laminate, plastic, ceramic, film or tape based substrates, printed circuit boards (PCBs) including fiber reinforced glass substrates such as FR4, BT resin substrates, metal lead frames of conductive metal (including copper, stainless steel, Alloy 42), and premolded leadframes (PMLFs) that include metal leads and mold compound formed together in a substrate. Further the term “substrate” includes another semiconductor device die or a portion of a semiconductor wafer so that in the arrangements, semiconductor device dies can be stacked facing one another for additional integration in a packaged device.

In this description, the term “ink jet deposition” is used. Ink jet deposition is an additive process for depositing a material on a surface. In printing, the term “ink jet printing” is used for additive deposition of ink using nozzles to dispense the ink as drops in patterns to form characters and symbols on a surface. In industrial applications, ink jet nozzles can deposit materials in an additive deposition to form layers on a surface. Ink jet deposition uses many fine nozzles coupled to ink reservoirs that include an electrical actuator. A piezoelectric actuator in a reservoir can force a small known volume of liquid material through a nozzle in response to an electrical signal. A thermal ink jet nozzle has a resistive element in the reservoir which heats and expands the ink to force a known volume of ink through a nozzle. In both cases as the ink falls the surface tension causes a spherical drop to form. Because the ink jet nozzles are so fine and because the nozzles include forming a drop in response to an electrical signal, the term “drop on demand” or “DOD” is used to describe the ability of ink jet deposition tools to precisely deposit a small quantity of liquid as the nozzle travels relative to a surface (moving either the surface or the nozzle with respect to the other). This precise drop placement results in a very efficient use of material to accurately place the material, and reduces waste and removes the need for cleaning or etch steps to remove unwanted material from portions of the surface. Masking and patterning steps are not needed with ink jet deposition, in contrast to sputtering or other methods. Removal of excess or unneeded material is also eliminated when ink jet deposition is used to deposit material.

In this description, the term “electrical terminal” is used. An electrical terminal is a terminal for making electrical connection to a semiconductor device die. Electrical terminals can include aluminum, copper or other conductive metals forming bond pads. Solder bumps, copper bumps, copper pillars and copper pillar bumps can be formed on the bond pads as part of the electrical terminals. The bumps of the electrical terminals can include additional platings such as nickel, palladium, tin, gold, solder and combinations such as ENIG (electroless nickel immersion gold) and ENEPIG (electroless nickel, electroless palladium, immersion gold) and combinations to promote solderability, increase adhesion, and to reduce or prevent corrosion or oxidation of metals, such as copper or aluminum. The term “electrical terminal” includes all of these arrangements for making electrical connections to a semiconductor device die. In this description, the term “thermo-compression” is used. As used herein, thermo-compression means the simultaneous application of elevated temperature and mechanical pressure. In examples, thermo-compression is used to bond a layer including conductive nanoparticles to a surface while simultaneously sintering the nanoparticles to form conductive paths. In this description, the terms “nanoparticle” and “nanosphere” are used. A nanoparticle or nanosphere is a particle or sphere with a diameter of between 1 and 100 nanometers. In this description the term “conductive nanoparticle” is used. A conductive nanoparticle includes nanoparticles and nanospheres coated with metal to form nanoparticles that will form conductors under thermal processing by sintering. An example sinterable ink material that includes metal conductive nanoparticles is a silver nanoparticle ink. In additional alternatives, the conductive nanospheres can be gold, copper, palladium, nickel, and combinations of these. In this description, the term “conductive lands” is used. A conductive land on a substrate is a conductive area for making an electrical connection to conductors in the substrate. Copper lands are often used, and aluminum, gold and other conductors can be used. Copper lands may be plated with nickel, gold, tin, palladium, and combinations of these to increase solderability, increase adhesion, and reduce or prevent corrosion or oxidation. In this description, a material is described as a “B-stage” material. A B-stage material is a material, such as a liquid, that can be partially cured to form a stable, solid layer, while remaining available to be completely cured at a later step. B-stage polymers used in bonding devices can be partially cured to form a layer of B-stage material. In example arrangements, a polymer layer can be partially cured to form a B-stage material, and this layer can then later be further and completely cured to bond two surfaces together.

In this description, elements are described as having “equal thickness.” Two elements have equal thickness when the outer surface of each element forms a common surface with the outer surface of the other element. However, in manufacturing, some deviation in thickness of either element can occur and this deviation can cause some slight differences in thickness between the two elements, and some portions of the common surface can be elevated or can decline with respect to the other portions of the common surface due to these manufacturing variances. If the two elements are intended to have equal thickness to form a common surface, as used herein the two elements are said to have equal thickness, even though some manufacturing deviations can and do occur.

In the arrangements, the problem of providing an electrical connection between a semiconductor device die and a substrate is solved by dispensing a material having conductive nanoparticles over the conductive lands on a substrate, while a polymer dielectric layer is dispensed between the lands on the substrate, to form a layer over the substrate. A semiconductor device die is aligned with the substrate and placed on the layer. Thermo-compression can be used to bond terminals of the semiconductor device die to the lands on the substrate by sintering conductive nanoparticles in the layer to form conductive paths between the devices. In example arrangements the sintered nanoparticles provide low resistance conductive paths in a z direction, without forming unwanted conductive paths in the x and y directions, preventing unwanted shorts between the pads.

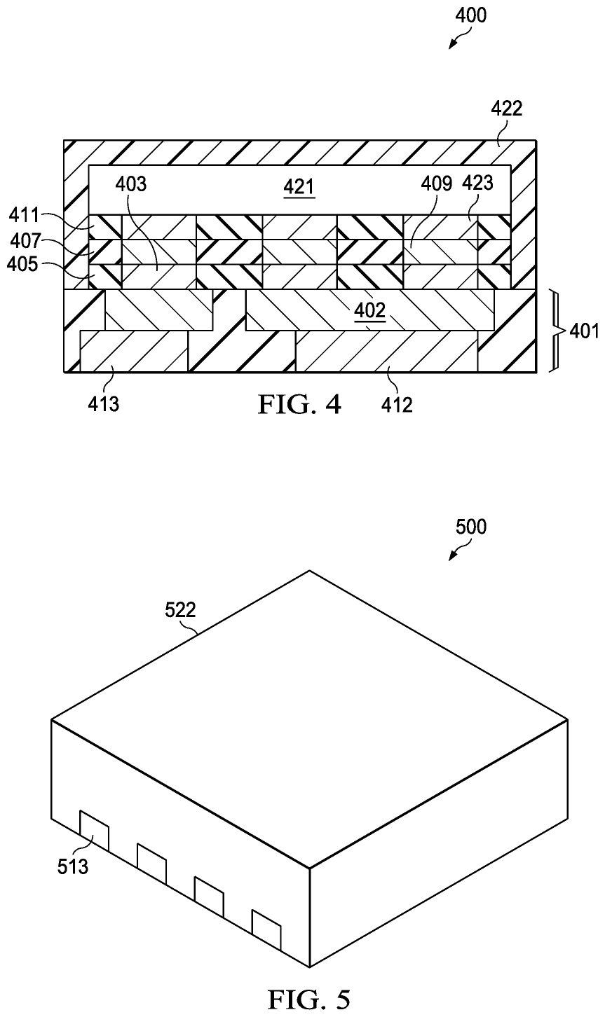

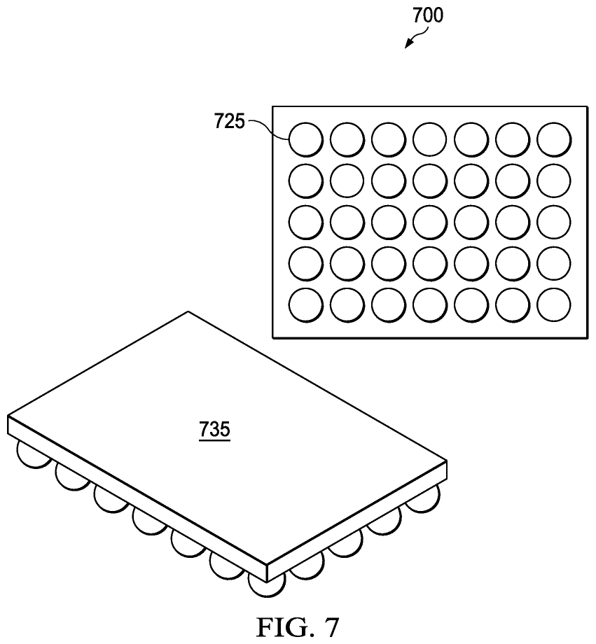

The arrangements disclosed herein are applicable to many “flip chip” device packages and to flip chip mounted devices. In a flip chip arrangement, a semiconductor device die has electrical terminals, which can include bond pads, and/or conductive bumps or pillars on the bond pads, arranged on a circuit side surface. The semiconductor device die is mounted to a substrate with the circuit side surface facing a device mounting area on the substrate, or “flipped” (when compared to arrangements where the circuit side surface faces away from the substrate.) Flip chip packages can include a substrate having an array of solder balls on an exposed outer surface to form a ball grid array (BGA) package. A BGA package useful with the arrangements is shown in FIG. 7. Example applications include forming multiple chip modules by flip chip mounting several semiconductor device dies to a substrate. In an example arrangement the substrate is a printed circuit board (PCB). The printed circuit board can include multiple layers of conductors laminated together and may be formed of a dielectric material. Materials used for PCBs include copper, aluminum, gold, and brass for conductors, and insulating materials such as fiber reinforced glass (FR4), BT resin, plastic films, ceramics, polyimides, plastic layers and tapes. A semiconductor device package can be formed where the substrate is a conductive lead frame and the semiconductor devices are encapsulated in mold compound after the semiconductor device die is mounted to the lead frame. Examples include quad flat no-lead (QFN) packages and leaded packages. A QFN package useful with the arrangements is shown in FIG. 5.

While some of the examples described illustrate using a single semiconductor device die on a substrate, multiple devices can be packaged together in the arrangements. Dies can be stacked in additional arrangements. High voltage components such as an FET device can be provided as a discrete device and packaged using a substrate and may be packaged with another device, for example with a FET gate driver circuit. Sensors or analog to digital converter ICs can be packaged with a digital integrated circuit to form a system on a chip (SOC or SOIC) packaged device. A packaged device that includes multiple semiconductor devices can be referred to as a system in a package (SIP). In some example arrangements, the substrate can be a portion of a semiconductor wafer including conductors for forming connections. In another example, the substrate can itself be another semiconductor device die, forming a stacked die arrangement.

To couple a flip chip mounted semiconductor device die to a substrate, vertical or “z” connections are needed. In some arrangements additional molding steps are needed.

In the arrangements, a substrate is provided with conductive lands arranged for receiving at least one semiconductor device die. The conductive lands are arranged in a correspondence with the electrical terminals on the semiconductor device die. Using ink jet deposition or another type of deposition, liquid material is dispensed to form a layer and cover the surface of the substrate between and around the conductive lands, while the upper surface of the conductive lands remains exposed. The material is a dielectric and may be provided as a polymer ink configured for ink jet nozzle dispensing, or as a liquid suitable for stencil printing. In an example the conductive lands extend from the surface of the substrate, and the polymer ink is dispensed to a thickness sufficient to form a layer of approximately equal thickness to form a more or less continuous surface with the outermost surface of the lands. In examples useful with the arrangements, the polymer may be one of polyimide, epoxy, bismaleimide resin, acrylate, and mixtures of these. The thickness of the polymer can be in a range from about 10 microns to a few hundred microns. The polymer can be cured to make it harder to better enable subsequent processes, for example by thermal cure or UV cure. In alternative examples, this step can be omitted.

In one example, additional dispensing of two more materials is done simultaneously by using ink jet deposition nozzles that traverse the surface area of the substrate. The two materials include additional polymer in the portions of the substrate between the conductive lands, and a material including conductive nanoparticles that is dispensed to cover the exposed surface of the conductive lands. The two materials are dispensed to form a layer of a more or less uniform thickness, the two materials being of approximately equal thickness, so the outermost exposed surface of the two materials forms a more or less continuous surface. In still another additional example arrangements the two materials are dispensed sequentially, in a sequence using one nozzle for both materials in sequence, or using different nozzles for dispensing the materials, but performing the dispensing in sequence. The second polymer can be B-stage materials which can be partially cured by heat or by UV to form a stable solid layer, so that the openings for the conductive lands are not disturbed by further processes. This step is optional and may be omitted. The conductive nanoparticle material can then be dispensed in a second deposition process by the same or another ink jet nozzle tool. The ink jet deposition nozzles can very accurately dispense each of the materials to form a desired pattern without need for photoresist, masking, or etching steps, even at very fine geometries. Thus the deposition process is cost effective and time efficient, and does not require acids or chemical treatments. Materials are very efficiently used and no removal of excess material is needed. The second polymer layer can be approximately an equal thickness as a thickness of the bump, this thickness typically ranges from a few microns to hundreds of microns.

After the conductive nanoparticles are deposited over the conductive lands on the substrate, additional polymer material is deposited on areas between the conductive lands, to form openings in a third polymer layer exposing the conductive nanoparticle materials. These openings correspond to electrical terminals on the semiconductor device die to be mounted to the substrate, and the thickness of the polymer layer so deposited corresponds to the thickness of the electrical terminals, whether a copper bump, pillar bump, ball or stud shape, to enable mounting of the semiconductor device with the electrical terminals on the conductive nanoparticle material as is further described hereinbelow.

In the arrangements, after the metal nanoparticles and the third polymer are dispensed on the substrate, a semiconductor device die is flip chip mounted to the substrate. In an example process, the semiconductor device die is aligned with the substrate so that the electrical terminals of the semiconductor device die are aligned in correspondence with the openings over the conductive lands on the substrate, the semiconductor device die is then placed in contact with the metal nanoparticle material and the third polymer. A thermo-compression bonding step is performed that sinters the conductive nanoparticles to form low resistance conductive paths between the electrical terminals of the semiconductor device die and the conductive lands on the substrate. The second and third polymer layers are cured during this process, to harden the material. In an example the thermo-compression step can be performed using a temperature of 130-250 degrees Celsius, and at a pressure of about 5 MegaPascals (MPa) for about 5 to 15 seconds. Depending on the characteristics of the nanoparticle ink and the polymers selected, in some arrangements additional curing and additional sintering can be performed by using a thermal process without the use of pressure to further cure the polymer layers and to increase conductivity in the nanoparticle ink. In an additional alternative arrangement, the first polymer layer can be stencil printed on the substrate instead of ink jet deposited.

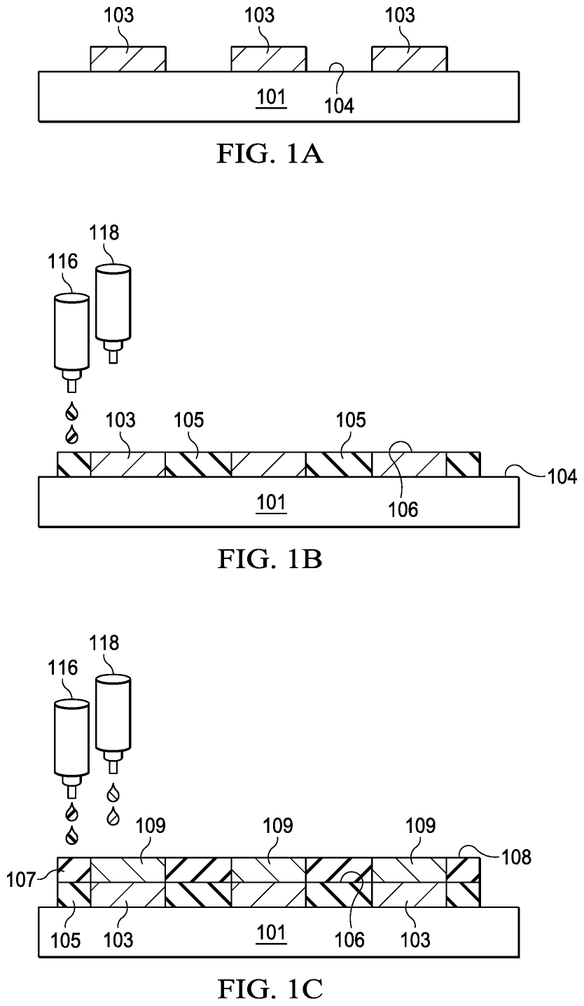

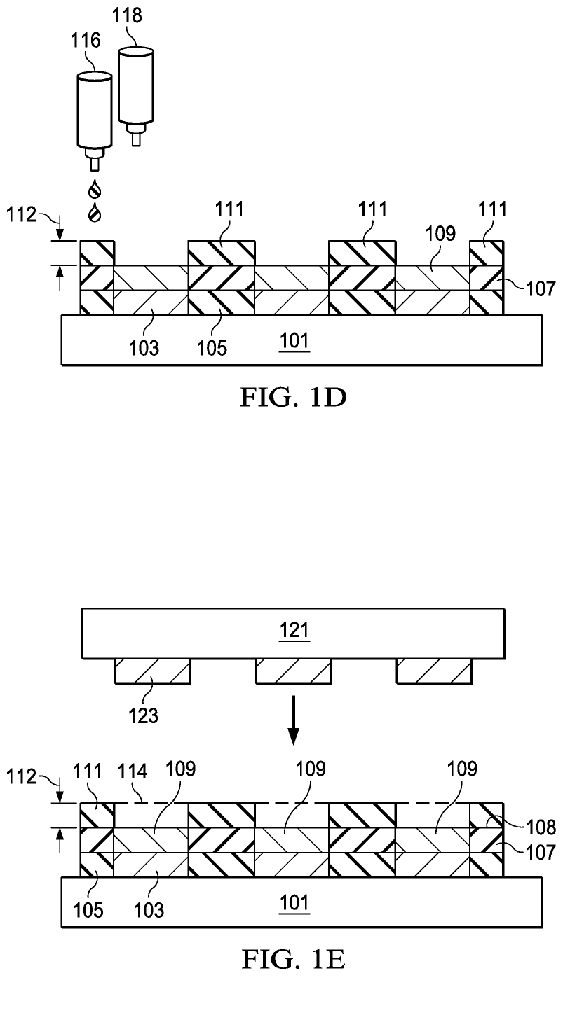

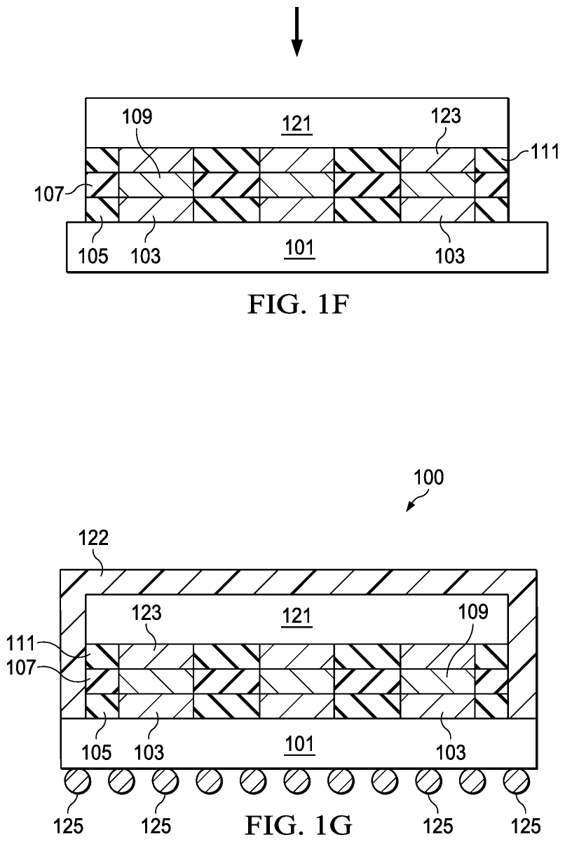

FIGS. 1A-1G are a series of cross sections illustrating selected steps of an example process. In FIG. 1A, a substrate 101 is shown oriented with a device mounting surface 104 facing upwards (as oriented FIGS. 1A-1G), the device mounting surface 104 having a plurality of conductive lands 103 in a pattern. In an example the conductive lands are copper and may include additional plating layers as described above. In additional arrangements, the lands 103 are of other conductive material. In FIG. 1B a first polymer is dispensed to form a layer 105 between the conductive lands 103 to a thickness that is approximately equal with a thickness of the conductive lands 103. The polymer 105 is an insulating dielectric and can be dispensed using ink jet deposition. As shown in FIG. 1B, polymer 105 can be dispensed by an ink jet deposition nozzle labeled 116. In an alternative arrangement the polymer layer 105 can be dispensed using a stencil deposition process. The upper surfaces (as oriented in FIG.1B) of the conductive lands 103 are at least partially exposed from the layer 105. In an example process the polymer layer 105 may be a B-stage material that can be partially cured to form a B-stage layer to increase stability and strength prior to additional processing. The partial cure of polymer layer 105 can be done by thermal or UV cure processes. In another example process this partial cure may not be done. The polymer layer 105 forms a surface 106 that is approximately coextensive with the upper surface of conductive lands 103, with the conductive lands exposed from polymer layer 105 at surface 106.

FIG. 1C illustrates in a cross sectional view the next steps in the example process. In FIG. 1C, two ink jet deposition nozzles are used to simultaneously dispense additional polymer material from nozzle 116, and conductive nanoparticle material from nozzle 118. Because in ink jet deposition the nozzles include the capability to form a “drop on demand” by sending electrical signals to the nozzles as the ink jet nozzles travel relative to the surface of the substrate, for example in a raster pattern, the two ink materials can be precisely deposited so that the conductive nanoparticles from 118 form areas 109 in a layer over only the conductive lands 103, while the additional polymer material from 116 forms areas 107 in a layer over only the first polymer layer 105 and not covering the lands 103. In this manner the two materials 107, 109 form an additional layer. The second polymer layer 107 can be subjected to a partial cure, such as a thermal or UV cure, depending on the material selected, to harden this layer prior to further processing. The polymer layer 107 has a surface 108 that is more or less a continuous surface between the polymer layer 107 and the conductive nanoparticle areas 109, although some deviation can occur in manufacturing so that the layer may have slight deviations in thickness. To form a layer of uniform and desired thickness, multiple thinner layers can be deposited in multiple passes. Alternatively a single pass can be used. Although two nozzles 116, 118 are shown in these examples for clarity of illustration, in an ink jet deposition tool many nozzles, for example tens or hundreds, can be used in a dispensing tool for each ink. In addition, the deposition tool can have multiple heads that traverse the substrate simultaneously or in some sequential pattern to more rapidly dispense the materials.

FIG. 1D depicts in another cross-sectional view an additional step where a third polymer layer is deposited. In FIG. 1D, an ink jet deposition tool 116 deposits another polymer layer 111. Polymer layer 111 is deposited to a thickness 112 that is selected to be more or less in correspondence with the height of the electrical terminals on the semiconductor device die (not shown in FIG. 1D) that will be flip chip mounted to substrate 101 as is further described hereinbelow. Polymer layer 111 is deposited on polymer layer 107 on surface 108, while the surface of the conductive nanoparticle areas 109 remains uncovered by this polymer layer 111, to enable electrical terminals (not shown in FIG. 1D, but see FIG. 1E as described hereinbelow) to meet the conductive nanoparticle areas when the semiconductor device die is flip chip mounted. The materials used for polymer layers described thus far, that is layer 105, layer 107, layer 111, can be the same polymer material. In alternative arrangements, the polymer layers can differ. For example, some of the polymer layers can be UV curable, while others are thermal cure material. The material used for the first polymer layer, 105, and the second polymer layer, 107, can be B-stage material that can be subjected to a partial cure to form a B stage layer, with additional curing occurring during later thermal processing described hereinbelow. The combination of various polymer layer types form additional alternative arrangements.

FIG. 1E depicts in a cross sectional view the next step in the example process. In FIG. 1E, a semiconductor device die 121 is placed, for example by a pick and place tool (not shown), in correspondence with and in a flip chip orientation to the substrate 101. Electrical terminals 123 are aligned in correspondence with the nanoparticle areas 109 that cover the conductive lands 103 on substrate 101. The semiconductor device die 121 is then brought into physical contact with the third polymer layer 111 and the nanoparticle areas 109. The height 112 of the third polymer layer is selected to be more or less in correspondence with the thickness of the electrical terminals 123 so that the electrical terminals 123 will be in contact with the conductive nanoparticle areas 109 when the semiconductor device die 121 makes contact with the upper surface 114 of the polymer layer 111.

In FIG. 1F, the semiconductor device die 121 and the substrate 101 are shown being bonded together using a combination of heat and pressure (thermo-compression) to simultaneously cure the polymer layers 105, 107, and 111, and to cause the sinterable nanoparticles in areas 109 to sinter and form low resistance conductive paths between the electrical terminals 123 on semiconductor device die 121 and the conductive lands 103 on the substrate 101. The thermo-compression step can be followed, in an example process, by additional thermal processing to further cure the polymer layers 105, 107 and 111, and further sinter the metal nanoparticles in areas 109 without applying mechanical pressure. In a further example arrangement, this additional cure is omitted. In an example the thermo-compression step can be performed using a temperature of 130-250 degrees Celsius, and at a pressure of about 5 MegaPascals (MPa), for about 5 to 15 seconds. Other values for temperature and pressure can be used to form alternative arrangements.

FIG. 1G illustrates in another cross sectional view a completed packaged semiconductor device arrangement 100. In FIG. 1G, the semiconductor device die 121 is bonded to substrate 101 by the sintered nanoparticles in areas 109 and the polymer layers 105, 107 and 111. A mold compound 122 covers portions of the substrate 101 on the device mounting side, but does not cover the opposing side, and may be described as an “overmold”. This mold compound layer 122 protects the semiconductor device die 121 and the polymer layers 105, 107. Alternatively, a metal lid (not shown) can be used to cover the die without molding compound. The substrate 101 in FIG. 1G further includes an array of solder balls or bumps 125 that completes the package 100, which is a ball grid array (BGA) type package. These solder balls or bumps can be added after the semiconductor device die 121 is mounted to substrate 101. The mold compound 122 can be formed using an encapsulation process using an epoxy, a resin, or an epoxy resin. Note that while the mold process is called “encapsulation”, portions of the substrate 101 are not covered by the mold compound even when it is encapsulated by the molding process, for example the bottom surface of substrate 101 in FIG. 1G. The mold compound 122 can include fillers to improve thermal transfer performance. The mold compound can be a liquid or a solid at room temperature and if a solid at room temperature, can be applied using a transfer mold or block mold by first heating the mold compound in a thermal chamber and then pressing it through runners into a mold containing the semiconductor device die and the substrate assembly. Liquid resin can be used as an alternative. A block mold press can be used. Multiple mounted devices can be molded at the same time and then separated one from another after the molding process is completed.

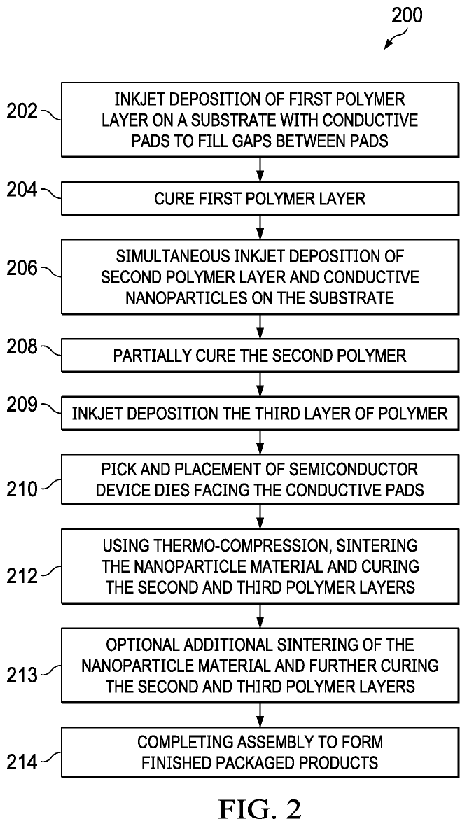

FIG. 2 is a flow diagram illustrating an example process for forming an arrangement such as shown in FIGS. 1A-1G. In FIG. 2, the process 200 begins at step 202, where ink jet deposition is performed to deposit a first polymer layer on a substrate between conductive lands, filling the gaps between the lands with a polymer layer that as a thickness that is approximately equal with a thickness of the lands. At step 204, a cure step is performed to at least partially cure the first polymer layer prior to further processing, the cure to harden and stabilize the first polymer layer. The cure can be a thermal cure or a UV cure, depending on the polymer type used for the first polymer layer.

At step 206, the process 200 continues by a simultaneous deposition of a second polymer layer and conductive nanoparticle areas. This step is illustrated at FIG. 1C, for example. In an example an ink jet deposition tool is used to simultaneously deposit the second polymer layer and the nanoparticle areas, so that the nanoparticle material is deposited on the surface of the conductive lands on the substrate. Note that as shown in FIG. 1B, when the first polymer layer is deposited the upper surface of the conductive lands is left exposed. The second polymer layer is deposited on the first polymer layer between the conductive lands so that the second polymer layer is not deposited over the conductive lands, and the second polymer layer and the metal nanoparticle areas form a more or less continuous upper surface between the two types of material.

At step 208, the second polymer layer can be partially cured to make the layer stable and less likely to be damaged by subsequent processes. The cure can again be UV or another light cure, thermal, or both, depending on the material used. The second polymer layer can be the same material as the first polymer layer, or in an alternative arrangements, can be a different material.

At step 209, the third polymer layer is deposited over the second polymer layer and between the areas of conductive nanoparticle material, as shown in FIG. 1D. The third polymer layer has a thickness that more or less corresponds to the thickness of the electrical terminals on a semiconductor die that is to be flip chip mounted to the substrate as described hereinbelow. FIG. 1D shows the deposition of the third polymer layer.

At step 210, a pick and place tool places a semiconductor device die over the substrate, with electrical terminals on die pads of the semiconductor device die placed in correspondence with the openings in the third polymer layer that correspond with the conductive lands on the substrate. This step is illustrated in FIG. 1E. The semiconductor device die is placed in physical contact with the metal nanoparticle areas and the second polymer layer.

At step 212, a thermo-compression step is performed. Heat and pressure are applied to press the semiconductor device die on the second and third polymer layers and the metal nanoparticle areas, and the heat of the thermal process cures the polymer layers and also sinters the nanoparticles. Conductive paths are formed between the conductive bumps on the bond pads of the semiconductor device die and the conductive lands on the substrate due to the sintering of the nanoparticles. This step is illustrated in FIG. 1F. In an example the thermo-compression step can be performed using a temperature of 130-250 degrees Celsius, and at a pressure of about 5 MegaPascals (MPa) for about 5 to 15 seconds. Other values for temperature and pressure can be used to form alternative arrangements.

At step 213 in FIG. 2, an optional additional thermal step is shown. In some example processes, the additional thermal step is used to further cure the polymer layers and to further sinter the sinterable nanoparticles. In other example processes, this step 213 may be omitted.

Step 214 in FIG. 2 illustrates the final step of the process, where the substrate and semiconductor device die are further protected by a mold compound and additional processes are performed to complete a packaged semiconductor device as shown in FIG. 1G.

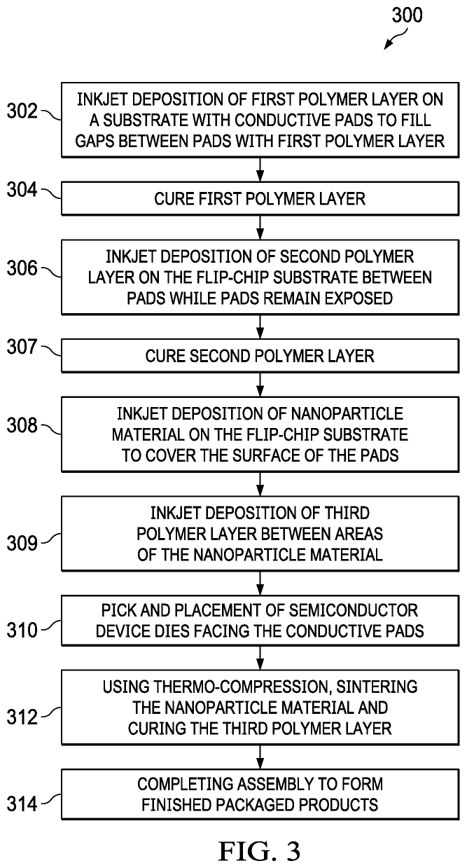

FIG. 3 illustrates in a flow diagram the steps of an alternative process 300 for forming an arrangement. Beginning at step 302, the first polymer layer is deposited on a substrate on a device mounting surface between conductive pads to form a layer that fills gaps between the pads. In an example process, an ink jet deposition process is used to dispense the first polymer layer. In an alternative arrangement, a stencil deposition process can be used.

In FIG. 3, at step 304, the process continues by performing at least a partial cure of the first polymer layer. The first polymer layer can be thermally cured or UV cured or other frequency light cured depending on the polymer. A full cure can also be performed depending on the material selected for the first polymer layer. As shown in FIG. 1B above, the first polymer fills the gaps between the conductive lands on the substrate, but does not cover the upper surface of the conductive lands, and the first polymer layer forms a more or less continuous surface with the upper surface of the conductive lands.

At step 306 of FIG. 3, another deposition is performed. In an example process an ink jet deposition tool is used to deposit the second polymer layer only on the first polymer layer, leaving the upper surface of the conductive lands exposed. At step 307, the second polymer layer can be cured. Again a thermal cure or a light or UV polymer cure can be used depending on the polymer material. If the second polymer layer is a B-stage material, a B stage layer can be formed to make the layer stable and less likely to be damaged by subsequent steps.

At step 308, another deposition is performed, to deposit the conductive nanoparticle material on the exposed surface of the conductive lands, and to form a more or less continuous surface with the second polymer layer. The result of the process after this step is the same as is shown in FIG. 1C, with the upper surface of the second polymer layer and the upper surface of the metal nanoparticles forming a surface layer.

At step 309 in FIG. 3, the third polymer layer is deposited on the second polymer layer between the areas of conductive nanoparticle material. This step is shown in FIG. 1D.

At step 310 in FIG. 3, a pick and place tool positions a semiconductor device die over the substrate with a circuit side surface facing the conductive lands on the substrate, and aligned so that the electrical terminals on the semiconductor device die are placed over the substrate in correspondence with the conductive nanoparticle material and aligned with the conductive lands on the substrate. This step corresponds to the cross section of FIG. 1E.

At step 312, the semiconductor device die is placed in contact with the second polymer layer and the conductive nanoparticle areas, and a combination of pressure and thermal energy, that is thermo-compression, is used to bond the semiconductor device die to the substrate. The heat in the thermo-compression process both cures the first, second and third polymer layers (if not previously cured), as well as sintering the conductive nanoparticle material to form low resistance conductive paths between the conductive terminals on the semiconductor device die and the conductive lands on the substrate, forming z direction connections without forming x or y direction connections. In an example the thermo-compression step can be performed using a temperature of 130-250 degrees Celsius, and at a pressure of about 5 MegaPascals (MPa) for about 5 to 15 seconds. Other values for temperature and pressure can be used to form alternative arrangements.

This result of this step is illustrated for example at FIG. 1F. In addition, additional thermal cure and sintering can be done without the use of pressure to further cure the polymer layers and to further sinter the conductive nanoparticle material. In another alternative process, the additional thermal processing can be omitted, depending on the materials used and the layer thicknesses.

At step 314, the assembly of the semiconductor device package is completed. As shown in FIG.1G, the semiconductor device die may be covered in a mold compound by encapsulation or overmolding. Alternatively, a metal lid can be used to cover the die without molding. In addition, a ball grid array package can include a plurality of solder balls on the opposite surface of the substrate for surface mounting to a system printed circuit board, for example, as shown in FIG. 1F.

FIG. 4 illustrates in a cross sectional view an arrangement where a semiconductor device die 421 is mounted on a substrate 401 with vertical connections formed using one of the deposition processes as described above, and forming a no-lead package arrangement. In FIG. 4, the reference numerals for elements similar to the elements of FIG. 1G are similar, for clarity of explanation. For example, semiconductor device die 421 corresponds to semiconductor device die 121 in FIG. 1G. In FIG. 4, a semiconductor device die 421 is flip chip mounted to a substrate 401. Electrical terminals 423 on the semiconductor device die 421 are aligned with and coupled to the conductive lands 403 on substrate 401. A first polymer layer 405 surrounds the conductive lands 403. A second polymer layer 407 has an upper surface that forms a more or less continuous surface with an upper surface of conductive nanoparticle areas 409 on lands 403. A third polymer layer 411 is formed on the second polymer layer 407 between the conductive nanoparticle areas 409. Low resistance paths formed by sintering the conductive nanoparticle areas 409 make connections in a z direction between the semiconductor device die electrical terminals 423 and the conductive lands 403 on substrate 401. In this example the substrate 401 is a metal lead frame that is subjected to a partial etch process, sometimes referred to as a “half-etch” lead frame, to form an upper layer 402 and a lower layer that includes leads 413 and a thermal or electrical pad 412. The lead frame can be formed by performing a partial etch from one side of substrate 401 to remove material, and a second partial etch from the opposite side to remove material, in some areas the two partial etches may combine to form openings that extend through the thickness of the lead frame, and in others ledges or corners may form in one or the other layer of the lead frame. Mold compound 422 can be disposed in the openings and removed areas to complete the substrate 401. These etch and molding steps can be done prior to use of the substrate to form a pre-molded lead frame (PMLF) for use as a substrate 401. After the semiconductor device die 421 is mounted to the substrate 401 and the thermo-compression step described above is performed to cure the polymer layers and sinter the conductive nanoparticles to form the low resistance electrical paths, an over molding step can be performed to form mold compound 422 to complete the packaged device 400.

FIG. 5 depicts in a projection view quad flat no leads (QFN) arrangement 500 that corresponds to the cross section in FIG. 4. IN FIG. 5, the mold compound 522 covers the semiconductor device die and at least the upper portion of the substrate. Package terminals 513 that are arranged for surface mounting of the packaged device 500 are shown, these correspond to the lead 413 in FIG. 4. Because the package terminals do not extend away from the body of the packaged semiconductor device, the package is described as a “no-leads” semiconductor package.

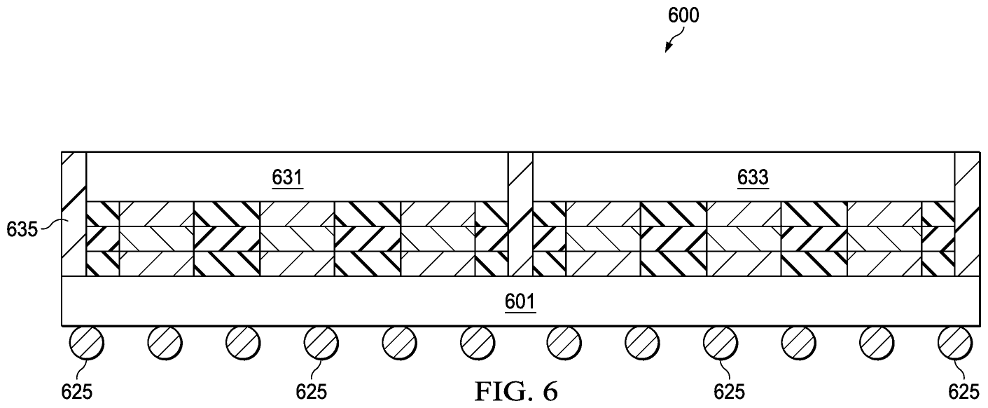

FIG. 6 illustrates in a cross section an arrangement 600 including multiple semiconductor device dies mounted to a substrate 601 using one of the example processes described above. In FIG. 6, a semiconductor device 631 and another semiconductor device 633 are shown mounted to substrate 601 and electrically coupled to the conductive lands on substrate 601 using the sintered conductive nanoparticles and the polymer layers as described above. While two semiconductor devices are shown in the example of FIG. 6, in alternative examples additional semiconductor device dies can be mounted to a substrate. In FIG. 6, solder balls 625 are used to form a ball grid array package, with an overmold of mold compound 635 covering at least the upper surface of substrate 601 and the semiconductor device dies.

FIG. 7 depicts in a projection view and a bottom plan view a ball grid array package 700 for use with the arrangements. In FIG. 7, the mold compound body 735 of the ball grid array package 700 is shown with ball grid array terminals 725. The BGA package 700 corresponds to the arrangement 600 in FIG. 6, with multiple semiconductor devices, or BGA package 100 in FIG. 1G. The arrangements can be packaged in other package types used for semiconductor devices.

Modifications are possible in the described arrangements, and other alternative arrangements are possible within the scope of the claims.

What is claimed is:

1. A packaged device, comprising:
a substrate having a device mounting surface and an opposing surface, the substrate having conductive lands having a first thickness spaced from one another on the device mounting surface;
a first polymer layer on the device mounting surface of the substrate between and surrounding the conductive lands and having a second thickness equal to the first thickness of the conductive lands, the conductive lands having an outer surface not covered by the first polymer layer, an outer surface of the first polymer layer and an outer surface of the conductive lands forming a common surface;
a second polymer layer on the first polymer layer, the second polymer layer having a third thickness, the outer surface of the conductive lands not covered by the second polymer layer;
conductive nanoparticle material on the outer surface of the conductive lands and having a fourth thickness equal to the third thickness, the outer surface of the second polymer layer and the outer surface of the conductive nanoparticle material forming a common surface;
a third polymer layer on the second polymer layer between the conductive nanoparticle material on the conductive lands, the conductive nanoparticle material having a surface exposed from the third polymer layer; and
at least one semiconductor device die mounted to the third polymer layer and having electrical terminals bonded to the conductive nanoparticle material.

2. The packaged device of claim 1, wherein the third polymer layer has a thickness that corresponds to a thickness of the electrical terminals of the semiconductor device die.

3. The packaged device of claim 1, wherein the first polymer layer is one selected from a group consisting essentially of polyimide, epoxy, bismaleimide resin, acrylate, and combinations of these.

4. The packaged device of claim 1, wherein the first polymer layer, the second polymer layer and the third polymer layer are one selected from a group consisting essentially of: polyimide, epoxy, bismaleimide resin, acrylate, and combinations of these.

5. The packaged device of claim 1, wherein the conductive nanoparticle material is a sinterable nanoparticle material.

6. The packaged device of claim 5 wherein the conductive nanoparticle material comprises metal.

7. The packaged device of claim 6 wherein the conductive nanoparticle material comprises silver.

8. The packaged device of claim 1 wherein the conductive nanoparticle material is one selected from a group consisting essentially of: silver, tin, nickel, copper, gold, palladium, alloys and combinations of these.

9. The packaged device of claim 1 and further comprising package terminals on a surface of the substrate opposite the device mounting surface.

10. The packaged device of claim 9 wherein the package terminals further comprise an array of solder balls to form a ball grid array package.

11. The packaged device of claim 9 wherein the package terminals form a no-lead package.

12. The packaged device of claim 1 wherein the substrate comprises a printed circuit board.

13. The packaged device of claim 1 wherein the substrate comprises a pre-molded lead frame.

14. The packaged device of claim 1 wherein the substrate comprises an additional semiconductor device die.

15. A method, comprising:
dispensing a first polymer layer surrounding conductive lands spaced from one another on a device mounting surface of a substrate, the first polymer layer having a first thickness equal to a second thickness of the conductive lands;
curing the first polymer layer, an outer surface of the conductive lands exposed from the first polymer layer;
dispensing a second polymer layer on the first polymer layer;
dispensing a conductive nanoparticle material on the exposed outer surface of the conductive lands;
dispensing a third polymer layer on the second polymer layer between the conductive lands, the conductive nanoparticle material exposed from the third polymer layer;
mounting a semiconductor device die on the third polymer layer, the semiconductor device die having electrical terminals aligned with and in contact with the conductive nanoparticle material over the conductive lands; and
applying pressure and heat to bond the semiconductor device die to the substrate, the heat curing the second and third polymer layers and sintering the conductive nanoparticle material to form electrical connections between the electrical terminals of the semiconductor device die and the conductive lands of the substrate.

16. The method of claim 15, wherein the dispensing of the first polymer layer is performed by an ink jet deposition process.

17. The method of claim 15, wherein the dispensing of the first polymer layer is performed by a stencil deposition process.

18. The method of claim 15 wherein the first polymer layer is UV curable.

19. The method of claim 15, wherein the first polymer layer is thermally curable.

20. The method of claim 15 wherein dispensing the second polymer layer and dispensing the conductive nanoparticle layer is performed simultaneously.

21. The method of claim 15, wherein dispensing the second polymer layer is performed prior to dispensing the conductive nanoparticle layer.

22. The method of claim 15, wherein dispensing the first polymer layer further comprises dispensing one selected from a group consisting essentially of polyimide, epoxy, bismaleimide resin, acrylate, and combinations of these.

23. The method of claim 15, wherein dispensing the first polymer layer, the second polymer layer and the third polymer layer each further comprises dispensing one selected from a group consisting essentially of polyimide, epoxy, bismaleimide resin, acrylate, and combinations of these.

24. The method of claim 15, wherein dispensing the conductive nanoparticle layer comprises dispensing one selected from a group consisting essentially of: silver, tin, nickel, copper, gold, palladium, alloys and combinations of these.

25. The method of claim 15, wherein dispensing the second polymer layer and dispensing the third polymer layer further comprise ink jet deposition.

26. The method of claim 15, wherein the third polymer layer is dispensed to a thickness that corresponds to a height of the electrical terminals on the semiconductor device die.
